(19) United States
(12) Patent Application Publication
(10) Pub. No.: US 2016/0146883 A1
(43) Pub. Date: May 26, 2016

(54) DEVICE AND METHOD OF DETECTING SIGNAL DELAY

(71) Applicant: UNIVERSAL SCIENTIFIC INDUSTRIAL (SHANGHAI) CO., LTD., Shanghai (CN)

(72) Inventor: Kuan-Hsing LI, Shanghai (CN)

(21) Appl. No.: 14/795,659

(22) Filed: Jul. 9, 2015

(30) Foreign Application Priority Data
Nov. 26, 2014 (CN) 201410696186.9

(51) Int. Cl. G01R 31/28

(52) U.S. Cl. CPC G01R 31/2882; G01R 31/2886

(57) ABSTRACT

The present disclosure discloses a device for, and a method of, detecting a signal delay. The method of detecting a signal delay includes inputting a first signal and a second signal to a logic circuit to obtain an output signal; measuring an average voltage of the output signal; and determining a delay time of the second signal relative to the first signal based on a difference between the average voltage of the output signal and a reference voltage. The device for detecting a signal delay includes a clock output of a clock generator connected to a first logic input of a logic circuit and to a connection area for receiving a circuit to be tested. A second logic input of the logic circuit is also connected to the connection area. The voltage measurement device is connected to a logic output of the logic circuit.

### CROSS-REFERENCE TO RELATED PATENT APPLICATIONS

This application claims the benefit of and priority to Chinese Patent Application No. 201410696186.9, filed on Nov. 26, 2014, the content of which is incorporated herein by reference in its entirety.

### BACKGROUND

1. Technical Field

The present disclosure relates to a signal detecting device and method, and more particularly to a method and device of detecting a delay time of an output signal of a circuit.

2. Description of the Related Art

Integrated circuits (ICs) implement increasingly more functions and are of decreasingly smaller size, while expected to have increasingly improved performance. However, impact from parasitic capacitance in a semiconductor component becomes more notable as feature size is reduced. The parasitic capacitance may give rise to a signal delay in a circuit. A measurement of signal delay can be a useful parameter for estimating the performance of a circuit. Therefore, it may be desirable to have a capability to accurately measure a delay time of an output signal of an IC.

An oscilloscope may be used to detect signals, display waveform representations of the sampled signals, and determine various aspects of the sampled signals. For example, an oscilloscope samples an input signal with a sampling rate, and displays a sampled waveform of the signal on a screen of the oscilloscope. The oscilloscope may perform measurement and calculation on the sampled signals and the displayed waveforms. However, an oscilloscope is expensive, and the wide variety of capabilities provided by an oscilloscope may be unnecessary to accomplish a measurement task.

Additionally, the sampling rates of many oscilloscopes are insufficient to sample high-frequency signals; therefore, sampling of a high-frequency signal may result in a distorted signal, and such distortion may lead to measurement inaccuracy.

Thus, it would be desirable to have available an alternative to the oscilloscope for the performance of certain measurement tasks, which alternative would be less expensive and more accurate.

### SUMMARY

In accordance with an embodiment of the present disclosure, a method of detecting a signal delay includes inputting a first signal and a second signal to a logic circuit to obtain an output signal; measuring an average voltage of the output signal; and determining a delay time of the second signal relative to the first signal according to a difference between the average voltage of the output signal and a reference voltage.

In accordance with an embodiment of the present disclosure, a device for detecting a signal delay includes a connection area to receive a circuit to be tested, the connection area including a first connection for an input end of the circuit to be tested and a second connection for an output end of the circuit to be tested. The device further includes a clock generator, where the clock generator includes a clock output connected to the first connection. The device further includes a logic circuit including a first logic input, a second logic input, and a logic output. The first logic input is connected to the clock output, and the second logic input is connected to the second connection. The device further includes a voltage measurement device connected to the logic output.

### BRIEF DESCRIPTION OF THE DRAWINGS

The disclosure will be described according to the appended drawings in which:

FIG. 1 is a block diagram of a system for detecting a signal delay according to an embodiment of the present disclosure;

FIG. 2 is a schematic diagram of a technique of detecting a signal delay according to an embodiment of the present disclosure;

FIG. 3A is a schematic diagram of a logic circuit according to an embodiment of the present disclosure;

FIG. 3B is an example of a timing diagram for the logic circuit of FIG. 3A;

FIG. 4A is a schematic diagram of a logic circuit according to an embodiment of the present disclosure;

FIG. 4B is an example of a timing diagram for the logic circuit of FIG. 4A;

FIG. 5A is a schematic diagram of a logic circuit according to an embodiment of the present disclosure; and

FIG. 5B is an example of a timing diagram for the logic circuit of FIG. 5A.

### DETAILED DESCRIPTION

The present disclosure describes a technique for detecting a signal delay, which may be implemented with relatively low cost, and which may provide improved accuracy for measuring signal delays of high-frequency signals.

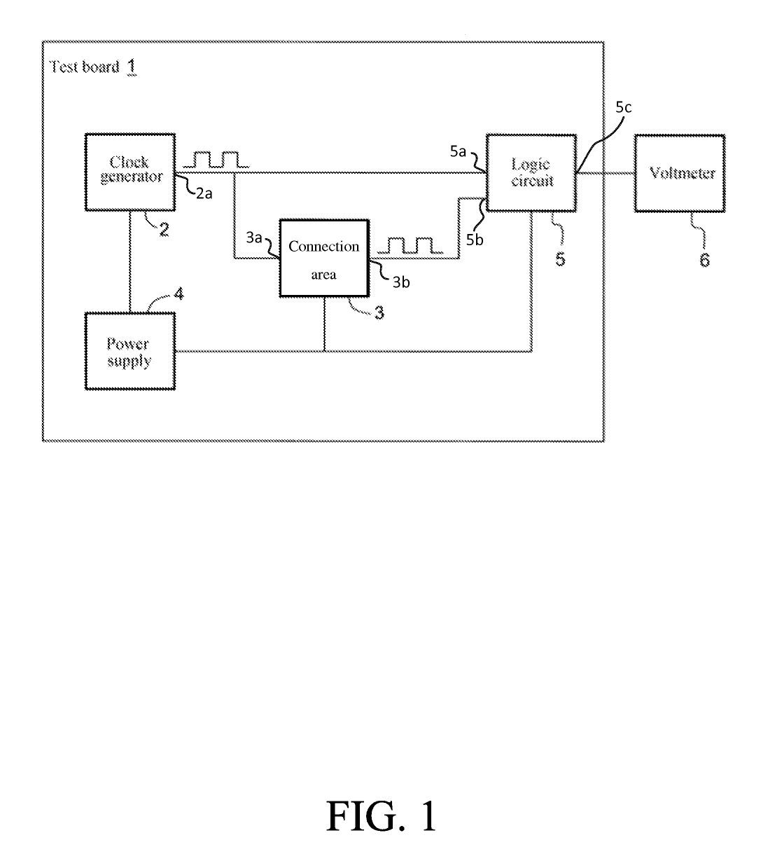

FIG. 1 is a block diagram of a system for detecting a signal delay according to an embodiment of the present disclosure. As shown in FIG. 1, a test board 1 includes a clock generator 2, a connection area 3, a power supply 4, and a logic circuit 5.

The test board 1 is a circuit board, which may be a printed circuit board or another suitable circuit board. The test board 1 may be a single-sided board, a double-sided board, or a multi-layer board.

The clock generator 2 is a circuit that is capable of generating signals at different frequencies. For example, the clock generator 2 may generate signals at a first frequency for a first test, at a second frequency for a second test, and at other frequencies for other tests. For another example, the clock generator 2 may generate a frequency sequence, such as a sweep signal (e.g., a chirp) that starts at a first frequency and repeatedly increments in frequency until a second frequency is reached. A clock output 2a of the clock generator 2 is connected to a first connection 3a of the connection area 3, and to a first logic input 5a of the logic circuit 5.

A circuit to be tested may be a discrete circuit or an IC. An input end of the circuit to be tested is connected to the first connection 3a of the connection area 3, and an output end of the circuit to be tested is connected to a second connection 3b of the connection area 3. The second connection 3b is connected to a second logic input 5b of the logic circuit 5.

The power supply 4 supplies power to the clock generator 2, the connection area 3 (for providing power to the circuit to be tested), and the logic circuit 5.

The logic circuit 5 generates an output signal at a logic output 5c according to logic levels of signals at the first logic input 5a and the second logic input 5b. As the signals at the first logic input 5a and the second logic input 5b change logic values, the output signal at the logic output 5c correspondingly changes. Thus, for the case in which the signals at the first logic input 5a and the second logic input 5b are periodic, the output signal at the logic output 5c has a duty cycle representing a phase difference between the signals at the first logic input 5a and the second logic input 5b.

According to an embodiment of the present disclosure, the logic circuit 5 may be one of an AND gate, a NAND gate, an OR gate, a NOR gate, an XOR gate, or a flip flop, or a combination thereof.

The system for detecting a signal delay further includes a voltmeter 6, shown as separate from the test board 1 in the embodiment illustrated in FIG. 1; however, the voltmeter 6 may be part of the test board 1 in other embodiments. The voltmeter 6 is capable of measuring an average voltage. The voltmeter 6 may be a stand-alone voltmeter, or may be, for example, a functionality included in a multimeter. In one or more embodiments of the present disclosure, the voltmeter 6 is capable of measuring a voltage less than 10 millivolts (mV). The voltmeter 6 is connected to the logic output 5c of the logic circuit 5, to measure a voltage of the output signal at the logic output 5c.

In the embodiment of the system for detecting a signal delay illustrated in FIG. 1, the clock generator 2 generates a first signal (e.g., a clock signal) at the clock output 2a, which is provided to the first connection 3a of the connection area 3, so as to be provided to the input end of the circuit to be tested, and is also provided to the first logic input 5a of the logic circuit 5. The circuit to be tested generates a second signal at the output end of the circuit to be tested according to the first signal. The second signal is provided from the output end of the circuit to be tested to the test board 1 such that the second signal is present at the second connection 3b of the connection area 3. The second signal present at the second connection 3b is provided to the second logic input 5b of the logic circuit 5. The logic circuit 5 generates an output signal at the logic output 5c according to the first signal received at the first logic input 5a and the second signal received at the second logic input 5b. The voltmeter 6 measures an average voltage of the output signal at the logic output 5c of the logic circuit 5.

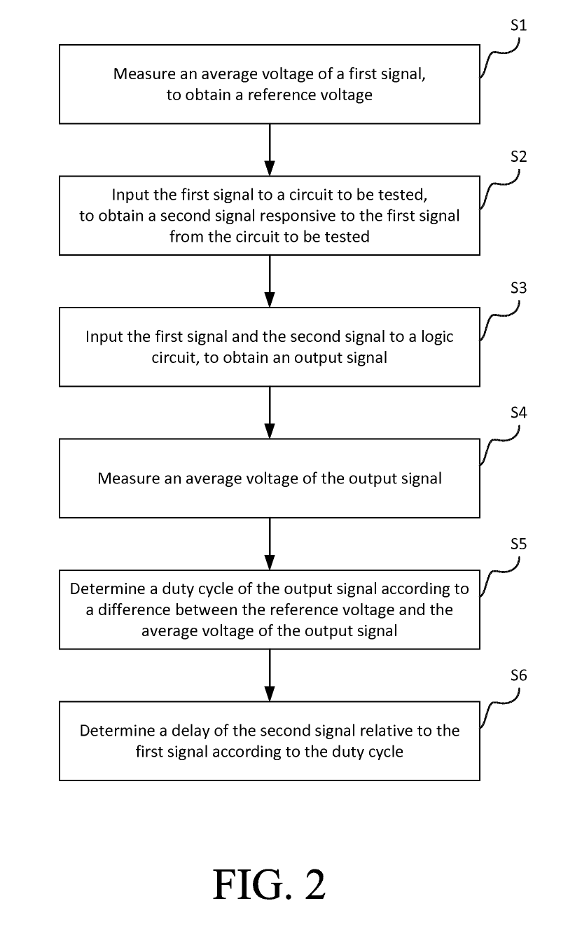

FIG. 2 is a diagram of a technique for detecting a signal delay according to an embodiment of the present disclosure, described with reference to the system for detecting a signal delay illustrated in FIG. 1. At S1, an average voltage of a first signal (e.g., the clock signal generated by the clock generator 2 and provided at the clock output 2a) is measured to obtain a reference voltage. At S2, the first signal is provided to the first connection 3a of the connection area 3, so as to be provided to the input end of the circuit to be tested, and a second signal responsive to the first signal from the output end of the circuit to be tested is provided to the test board 1 such that it is available at the second connection 3b of the connection area 3. At S3, the first signal and the second signal from the second connection 3b are provided to the first logic input 5a and the second logic input 5b, respectively, to obtain an output signal at the logic output 5c of the logic circuit 5. At S4, an average voltage of the output signal at the logic output 5c is measured. At S5, a duty cycle of the output signal at the logic output 5c is determined according to a difference between the reference voltage (obtained at S1) and the average voltage of the output signal at the logic output 5c. At S6, a signal delay of the second signal received at the second logic input 5b relative to the first signal received at the first logic input 5a is determined according to the duty cycle determined at S5.

According to an embodiment of the present disclosure, the first signal (e.g., the clock signal generated by the clock generator 2) provided to the first logic input 5a of the logic circuit 5 is a square wave, and the second signal received at the second logic input 5b is a square wave.

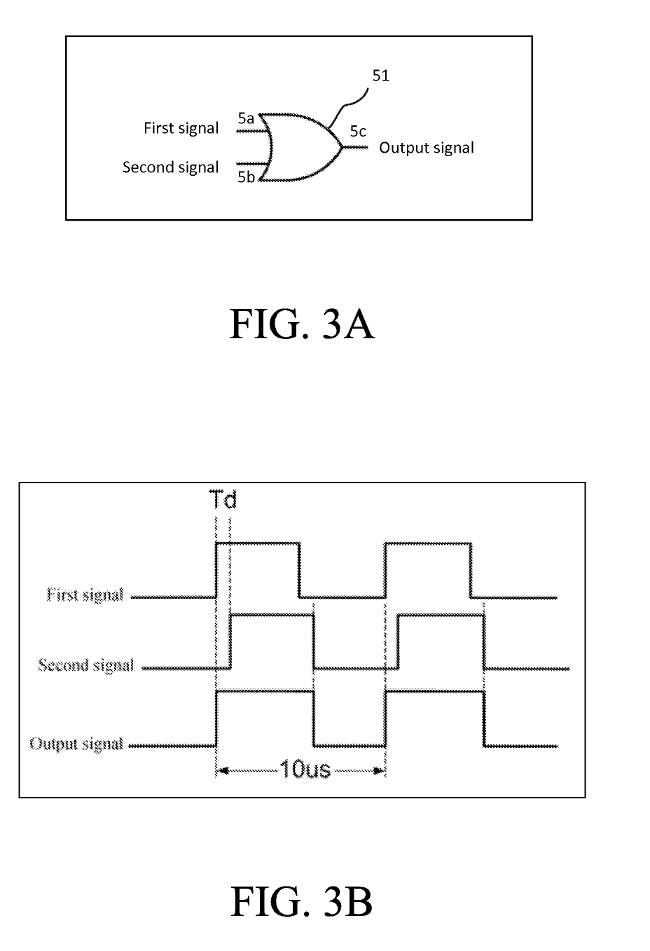

FIG. 3A is a schematic diagram of a logic circuit 51 according to an embodiment of the present disclosure. Logic circuit 51 is the logic circuit 5 of FIG. 1 including an OR gate, with the first logic input 5a receiving a first signal, the second logic input 5b receiving a second signal, and the logic output 5c providing an output signal. FIG. 3B illustrates an example of an output signal responsive to the first signal and the second signal. With reference also to FIG. 1, the first signal is a square wave that is generated by the clock generator 2 with a period of 10 microseconds (μs) (frequency of 100 kilohertz (KHz)), and the second signal is a square wave that is received from the second connection 3b, responsive to the first signal being input to the circuit to be tested by way of the first connection 3a. The second signal received at the second logic input 5b may be delayed by a delay time (labeled as Td in FIG. 3B) with respect to the first signal received at the first logic input 5a. When the first signal and the second signal as shown in FIG. 3B are input to the OR gate (FIG. 3A), the OR gate outputs the output signal shown in FIG. 3B. A duty cycle of the output signal reflects the delay time of the second signal. In some embodiments, a duty cycle refers to a fraction or a percentage of one period in which a signal is active. In the example of FIG. 3B, a signal delay translates into a higher duty cycle of the output signal. An average value of the output signal voltage may be measured to represent the duty cycle, and the delay time of the second signal may be determined by comparing the average value of the output signal to a reference voltage.

The voltmeter 6 shown in FIG. 1 may be used to measure an average voltage of the output signal, and may further be used to measure an average voltage of the first signal to obtain a reference voltage. A comparison of the average voltage of the output signal to the reference voltage may be used to determine a duty cycle of the output signal, which in turn may be used to determine the signal delay of the second signal relative to the first signal.

Table 1 provides three illustrations, for the case in which the logic circuit 5 of FIG. 1 includes the logic circuit 51 with the OR gate as illustrated in the embodiment of FIG. 3A. For the illustrations in Table 1, the first signal at the first logic input 5a has a logic high voltage (a peak voltage) of 1.8 V and a duty cycle of 50%, and therefore has an average value of 900 millivolts (mV). In Table 1, the first column indicates the average voltage of the output signal measured at the logic output 5c; the second column indicates a difference between the reference voltage (for example, the average voltage of the clock signal in FIG. 1, or the average voltage of the first signal in FIG. 3A) and the average voltage of the output signal measured at the logic output 5c. The third column of Table 1 is a duty cycle determined from the voltage difference of the second column, and the fourth column is a delay time of the second signal relative to the first signal, determined from the duty cycle in the third column.

TABLE 1

| | Difference between | | |
|---|---|---|---|
| | the reference voltage | | |
| | and the average | | |
| Average voltage of | voltage of the output | | |
| the output signal | signal | Duty cycle | Delay time |
| 900 mV | 0 mV | 50% | 0 ns |
| 936 mV | 36 mV | 52% | 200 ns |
| 990 mV | 90 mV | 55% | 500 ns |

According to the second row of Table 1, for an average voltage of the output signal of 900 mV, there is a difference of 0 V with respect to the reference voltage. Therefore, the duty cycle of the output signal is determined to be 50%, and it is further determined that the second signal is not delayed relative to the first signal.

According to the third row of Table 1, for an average voltage value of the output signal of 936 mV, there is a difference of 36 mV with respect to the reference voltage. Therefore, the duty cycle of the output signal is determined to be 52%, and it is further determined that the delay time of the second signal relative to the first signal is 200 nanoseconds (ns).

Similarly, according to the fourth row of Table 1, it can be determined that the delay time of the second signal relative to the first signal is 500 ns for a measured average voltage of the output signal equal to 990 mV.

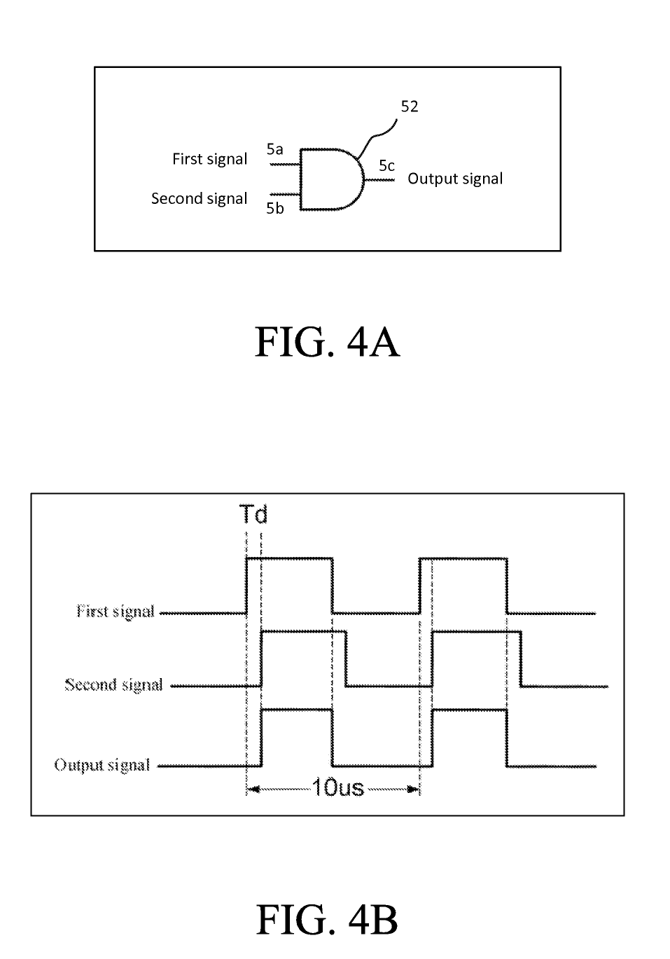

FIG. 4A is a schematic diagram of a logic circuit 52 according to an embodiment of the present disclosure. The logic circuit 52 is the logic circuit 5 of FIG. 1 including an AND gate, with the first logic input 5a receiving a first signal, the second logic input 5b receiving a second signal, and the logic output 5c providing an output signal. FIG. 4B illustrates an example of an output signal responsive to the first signal and the second signal. With reference also to FIG. 1, the first signal is a square wave that is generated by the clock generator 2 with a period of 10 μs (frequency of 100 KHz), and the second signal is a square wave that is received from the second connection 3b, responsive to the first signal being input to the circuit to be tested by way of the first connection 3a. The second signal received at the second logic input 5b may be delayed by a delay time (labeled as Td in FIG. 4B) with respect to the first signal received at the first logic input 5a. When the first signal and the second signal as shown in FIG. 4B are input to the AND gate (FIG. 4A), the AND gate outputs the output signal shown in FIG. 4B. A duty cycle of the output signal reflects the delay time of the second signal. In the example of FIG. 4B, a signal delay translates into a lower duty cycle of the output signal. An average value of the output signal voltage may be measured to represent the duty cycle, and the delay time of the second signal may be determined by comparing the average value of the output signal to a reference voltage.

The voltmeter 6 shown in FIG. 1 may be used to measure an average voltage of the output signal, and may further be used to measure an average voltage of the first signal to obtain a reference voltage. A comparison of the average voltage of the output signal to the reference voltage may be used to determine a duty cycle of the output signal, which in turn may be used to determine the signal delay of the second signal relative to the first signal.

Table 2 provides three illustrations, for the case in which the logic circuit 5 of FIG. 1 includes the logic circuit 52 with the AND gate as illustrated in the embodiment of FIG. 4A. For the illustrations in Table 2, the first signal at the first logic input 5a has a logic high voltage (a peak voltage) of 1.8 V and a duty cycle of 50%, and therefore has an average value of 900 mV. In Table 2, the first column indicates the average voltage of the output signal measured at the logic output 5c; the second column indicates a difference between the reference voltage (for example, the average voltage of the clock signal in FIG. 1, or the average voltage of the first signal in FIG. 4A) and the average voltage of the output signal measured at the logic output 5c. The third column of Table 2 is a duty cycle determined from the voltage difference of the second column, and the fourth column is a delay time of the second signal relative to the first signal, determined from the duty cycle in the third column.

TABLE 2

| | Difference between | | |
|---|---|---|---|
| | the reference voltage | | |
| | and the average | | |
| Average voltage of the | voltage of the output | | |
| output signal | signal | Duty cycle | Delay time |
| 900 mV | 0 mV | 50% | 0 ns |
| 864 mV | 36 mV | 48% | 200 ns |
| 810 mV | 90 mV | 45% | 500 ns |

According to the second row of Table 2, for an average voltage of the output signal of 900 mV, there is a difference of 0 V with respect to the reference voltage. Therefore, the duty cycle of the output signal is determined to be 50%, and it is further determined that the second signal is not delayed relative to the first signal.

According to the third row of Table 2, for an average voltage value of the output signal of 864 mV, there is a difference of 36 mV with respect to the reference voltage. Therefore, the duty cycle of the output signal is determined to be 48%, and it is further determined that the delay time of the second signal relative to the first signal is 200 ns.

Similarly, according to the fourth row of Table 2, it can be determined that the delay time of the second signal relative to the first signal is 500 ns for a measured average voltage of the output signal equal to 810 mV.

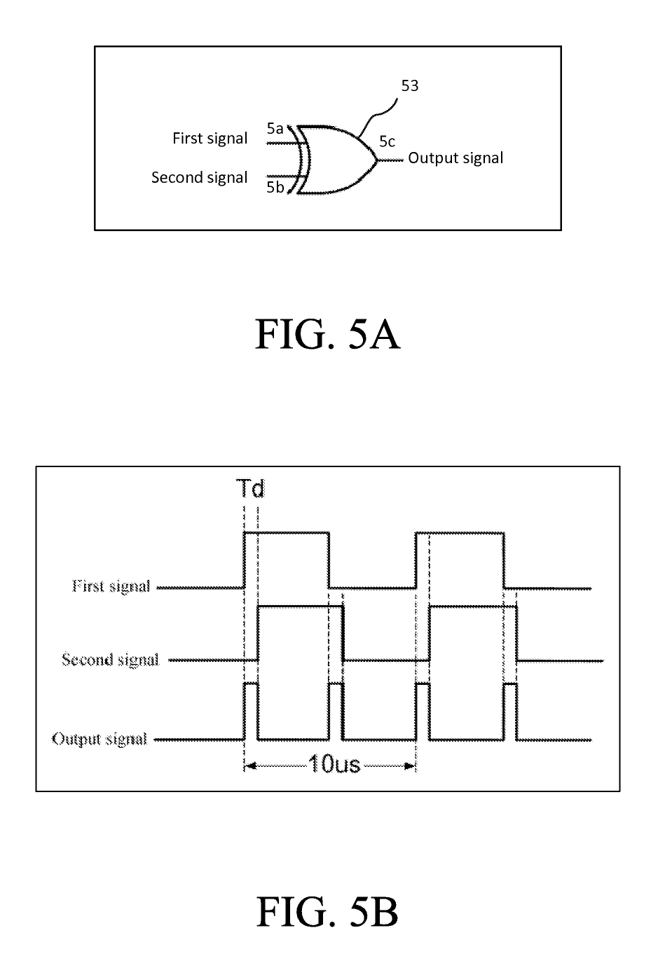

FIG. 5A is a schematic diagram of a logic circuit 53 according to an embodiment of the present disclosure. The logic circuit 53 is the logic circuit 5 of FIG. 1 including a XOR gate, with the first logic input 5a receiving a first signal, the second logic input 5b receiving a second signal, and the logic output 5c providing an output signal. FIG. 5B illustrates an example of an output signal responsive to the first signal and the second signal. With reference also to FIG. 1, the first signal is a square wave that is generated by the clock generator 2 with a period of 10 μs (frequency of 100 KHz), and the second signal is a square wave that is received from the second connection 3b, responsive to the first signal being input to the circuit to be tested by way of the first connection 3a. The second signal received at the second logic input 5b may be delayed by a delay time (labeled as Td in FIG. 5B) with respect to the first signal received at the first logic input 5a. When the first signal and the second signal as shown in FIG. 5B are input to the XOR gate (FIG. 5A), the NOR gate outputs the output signal shown in FIG. 5B. A duty cycle of the output signal reflects the delay time of the second signal. An average value of the output signal voltage may be measured to represent the duty cycle, and the delay time of the second signal may be determined by comparing the average value of the output signal to a reference voltage.

The voltmeter 6 shown in FIG. 1 may be used to measure an average voltage of the output signal, and may further be used to measure an average voltage of the first signal to obtain a reference voltage. A comparison of the average voltage of the output signal to the reference voltage may be used to determine a duty cycle of the output signal, which in turn may be used to determine the signal delay of the second signal relative to the first signal.

Table 3 provides three illustrations, for the case in which the logic circuit 5 of FIG. 1 includes the logic circuit 53 with the XOR gate as illustrated in the embodiment of FIG. 5A. For the illustrations in Table 3, the first signal at the first logic input 5a has a logic high voltage (a peak voltage) of 1.8 V and a duty cycle of 50%, and therefore has an average value of 900 mV. In Table 3, the first column indicates the average voltage of the output signal measured at the logic output 5c; the second column indicates a difference between the reference voltage (for example, the average voltage of the clock signal in FIG. 1, or the average voltage of the first signal in FIG. 5A) and the average voltage of the output signal measured at the logic output 5c. The third column of Table 3 is a duty cycle determined from the voltage difference of the second column, and the fourth column is a delay time of the second signal relative to the first signal, determined from the duty cycle in the third column.

TABLE 3

| | Difference between | | |
|---|---|---|---|
| | the reference voltage | | |
| | and the average | | |
| Average voltage of the | voltage of the output | | |
| output signal | signal | Duty cycle | Delay time |
| 0 mV | 900 mV | 0% | 0 ns |
| 72 mV | 828 mV | 4% | 200 ns |
| 180 mV | 720 mV | 10% | 500 ns |

According to the second row of Table 3, for an average voltage of the output signal of 0 my, there is a difference of 900 mV with respect to the reference voltage. Therefore, the duty cycle of the output signal is determined to be 0%, and it is further determined that the second signal is not delayed relative to the first signal.

According to the third row of Table 3, for an average voltage value of the output signal of 72 mV, there is a difference of 828 mV with respect to the reference voltage. Therefore, the duty cycle of the output signal is determined to be 4%, and it is further determined that the delay time of the second signal relative to the first signal is 200 ns.

Similarly, according to the fourth row of Table 3, it can be determined that the delay time of the second signal relative to the first signal is 500 ns for a measured average voltage of the output signal equal to 180 mV.

As can be seen from Tables 1, 2 and 3, different compositions of the logic circuit 5 (e.g., logic circuit 51 in FIG. 3A, logic circuit 52 in FIG. 4A, and logic circuit 53 in FIG. 5A) result in different relationships between the delay time of the second signal relative to the first signal, and different relationships between the average voltage of the output signal and the reference voltage. Accordingly, in addition to the embodiments shown in FIGS. 3A, 4A and 5A, other circuits may be used in the logic circuit 5 of the present disclosure. Therefore, the embodiments in FIGS. 3A, 4A and 5A are provided by way of illustration, and do not limit the scope of the present disclosure.

In one or more embodiments, an actual value of a delay time is not needed; rather, it is sufficient if the delay time is less than or equal to a predetermined delay time. In such a case, an average voltage of the output signal of the logic circuit 5 may be compared to a reference voltage that is known to represent the predetermined delay time; for example, a measured average voltage of the output signal may be used to accept or reject the circuit to be tested based on a comparison to the reference voltage.

A benefit of the techniques of the present disclosure is a reduction in testing costs. The average voltage of the output signal of the logic circuit 5 can be measured using the voltmeter 6, thereby deriving a delay time of a circuit to be tested without relatively expensive equipment such as an oscilloscope.

Another benefit of the technique described in this disclosure is that high-frequency signals may be used to determine a delay of a circuit to be tested, thus the circuit to be tested may be tested at frequencies representative of frequencies expected during operation. In other words, the test technique using a voltmeter is not affected by the frequency used in the test. By way of comparison, to test signal delay in the presence of high-frequency signals, an oscilloscope with a high sampling rate is needed, to avoid distortion.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of detecting a signal delay, comprising:
inputting a first signal and a second signal to a logic circuit to obtain an output signal;
measuring an average voltage of the output signal; and
determining a delay time of the second signal relative to the first signal according to a difference between the average voltage of the output signal and a reference voltage.

2. The method according to claim 1, further comprising determining an average voltage of the first signal, to obtain the reference voltage.

3. The method according to claim 1, further comprising operating the logic circuit to obtain the output signal according to a phase difference between the first signal and the second signal.

4. The method according to claim 3, wherein the output signal has a duty cycle, further comprising determining a delay time of the second signal relative to the first signal according to the duty cycle of the output signal.

5. The method according to claim 1, further comprising operating the logic circuit to obtain a logic value of the output signal according to a relationship between logic values of the first signal and the second signal.

6. The method according to claim 5, wherein the logic circuit is one of an AND gate, a NAND gate, an OR gate, a NOR gate, an XOR gate, or a flip flop, or a combination thereof.

7. The method according to claim 1, wherein the first signal and the second signal are square waves.

8. The method according to claim 1, wherein measuring the average voltage of the output signal is performed using a voltmeter capable of measuring average voltages.

9. The method according to claim 8, wherein the voltmeter is a multimeter.

10. The method according to claim 8, wherein the voltmeter is capable of measuring a voltage less than 10 millivolts.

11. A device for detecting a signal delay, comprising:
a connection area configured to receive a circuit to be tested, the connection area including a first connection for an input end of the circuit to be tested and a second connection for an output end of the circuit to be tested;
a clock generator comprising a clock output connected to the first connection;
a logic circuit comprising a first logic input, a second logic input, and a logic output, wherein the first logic input is connected to the clock output, and the second logic input is connected to the second connection; and
a voltage measurement device connected to the logic output.

12. The device according to claim 11, wherein the logic circuit is configured to receive a first signal at the first logic input and a second signal at the second logic input, and to provide an output signal at the logic output according to the first signal and the second signal.

13. The device according to claim 12, wherein the logic circuit is further configured to determine a logic value for the output signal according to a relationship between logic values of the first signal and the second signal.

14. The device according to claim 12, wherein the voltage measurement device is configured to determine an average voltage of the output signal, and wherein a difference between the average voltage of the output signal and a reference voltage represents a delay time of the second signal relative to the first signal.

15. The device according to claim 14, wherein the reference voltage is an average voltage of the first signal.

16. The device according to claim 12, wherein a duty cycle of the output signal represents a phase difference between the first signal and the second signal.

17. The device according to claim 16, wherein the logic circuit is further configured to provide an output signal at the logic output, wherein the output signal has a duty cycle related to a delay time of the second signal relative to the first signal.

18. The device according to claim 11, wherein the logic circuit is one of an AND gate, a NAND gate, an OR gate, a NOR gate, an XOR gate, or a flip flop, or a combination thereof.

19. The device according to claim 11, further comprising a power supply, wherein the power supply is configured to provide power to the clock generator, the logic circuit, and the connection area.

20. The device according to claim 11, wherein the voltage measurement device is a voltmeter or a multimeter.
